(19) United States
(12) Patent Application Publication
(10) Pub. No.: US 2026/0282517 A1
(43) Pub. Date: Sep. 17, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Hiroki NEMOTO, Meguro Tokyo (JP); Tomoaki INOKUCHI, Yokohama Kanagawa (JP); Shotaro BABA, Kawasaki Kanagawa (JP); Tatsuya NISHIWAKI, Yokohama Kanagawa (JP); Yusuke KOBAYASHI, Yokohama Kanagawa (JP); Kairu YOSHIDA, Kawasaki Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/529,241

(22) Filed: Feb. 4, 2026

(30) Foreign Application Priority Data
Mar. 14, 2025 (JP) 2025-041483

(51) Int. Cl. H10D 84/00; H10D 64/00; H10D 64/27; H10D 84/01

(52) U.S. Cl. CPC H10D 84/146; H10D 64/117; H10D 64/519; H10D 84/0109

(57) ABSTRACT

According to one embodiment, a semiconductor device includes first to third electrodes, a first conductive member, a semiconductor member, a first insulating member, first and second connection members. The first connection member includes a first connection portion. The second connection member includes a first portion. The first connection portion includes a first material belonging to a second type material group. The first connection portion is electrically connected to the first conductive member. The first portion includes a second material belonging to a first type material group different from the second type material group. The first portion is electrically connected to the third electrode. The first electrode member is between the semiconductor member and the second electrode. The first electrode member includes a third material belonging to the first type material group. The first electrode member is in Schottky contact with the semiconductor member.

### CROSS-REFERENCE TO RELATED APPLICATIONS

This application is based upon and claims the benefit of priority from Japanese Patent Application No. 2025-041483, filed on Mar. 14, 2025; the entire contents of which are incorporated herein by reference.

### FIELD

Embodiments described herein relate generally to a semiconductor device.

### BACKGROUND

For example, in semiconductor devices, improvements in characteristics are desired.

### BRIEF DESCRIPTION OF THE DRAWINGS

FIGS. 1A, 1B, and 1C are schematic cross-sectional views illustrating a semiconductor device according to a first embodiment;

FIG. 2 is a schematic plan view illustrating the semiconductor device according to the first embodiment;

FIGS. 3A and 3B are schematic plan views illustrating the semiconductor device according to the first embodiment;

FIGS. 4A and 4B are schematic cross-sectional views illustrating the semiconductor device according to the first embodiment;

FIGS. 5A and 5B are schematic cross-sectional views illustrating the semiconductor device according to the first embodiment;

FIGS. 6A and 6B are schematic cross-sectional views illustrating semiconductor devices according to the first embodiment;

FIGS. 7A, 7B, and 7C are schematic cross-sectional views illustrating semiconductor devices according to the first embodiment;

FIGS. 8A, 8B, and 8C are schematic cross-sectional views illustrating semiconductor devices according to the first embodiment;

FIG. 9 is a schematic cross-sectional view illustrating a semiconductor device according to the first embodiment;

FIGS. 10A and 10B are schematic cross-sectional views illustrating semiconductor devices according to the first embodiment;

FIGS. 11A and 11B are schematic cross-sectional views illustrating a semiconductor device according to the first embodiment;

FIGS. 12A and 12B are schematic cross-sectional views illustrating semiconductor devices according to the first embodiment;

FIGS. 13A, 13B, and 13C are schematic cross-sectional views illustrating semiconductor devices according to the first embodiment;

FIG. 14 is a schematic cross-sectional view illustrating a semiconductor device according to the first embodiment;

FIGS. 15A and 15B are schematic cross-sectional views illustrating semiconductor devices according to the first embodiment;

FIG. 16 is a schematic cross-sectional view illustrating a semiconductor device according to the first embodiment;

FIGS. 17A and 17B are schematic cross-sectional views illustrating semiconductor devices according to the first embodiment;

FIG. 18 is a schematic diagram illustrating a method for manufacturing a semiconductor device according to the first embodiment; and

FIG. 19 is a schematic diagram illustrating a method for manufacturing a semiconductor device according to the first embodiment.

### DETAILED DESCRIPTION

According to one embodiment, a semiconductor device includes a first electrode, a second electrode, a third electrode, a first conductive member, a semiconductor member, a first insulating member, a first connection member, and a second connection member. The second electrode includes a first electrode member. A direction from the first electrode to the second electrode is along a first direction. The third electrode is provided between the first electrode and the second electrode. The third electrode includes polysilicon of a second conductivity type. The first conductive member is provided between the first electrode and the third electrode in the first direction. The first conductive member includes polysilicon of a first conductivity type. The semiconductor member is provided between the first electrode and the second electrode. The semiconductor member includes a first semiconductor region of the first conductivity type and a second semiconductor region of the first conductivity type. The second semiconductor region is between the first semiconductor region and the second electrode. A direction from a part of the third electrode to the second semiconductor region crosses the first direction. At least a part of the first insulating member is between the first conductive member and the semiconductor member and between the third electrode and the semiconductor member. The first connection member includes a first connection portion. The second connection member includes a first portion. The first connection portion includes a first material belonging to a second type material group. The first connection portion is electrically connected to the first conductive member. The first portion includes a second material belonging to a first type material group different from the second type material group. The first portion is electrically connected to the third electrode. The first electrode member is between the semiconductor member and the second electrode. The first electrode member includes a third material belonging to the first type material group. The first electrode member is in Schottky contact with the semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

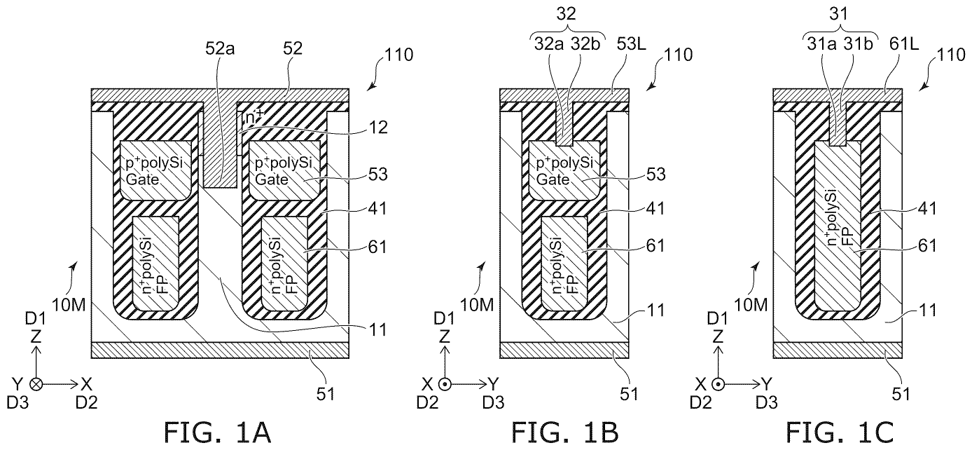

FIGS. 1A, 1B, and 1C are schematic cross-sectional views illustrating a semiconductor device according to a first embodiment.

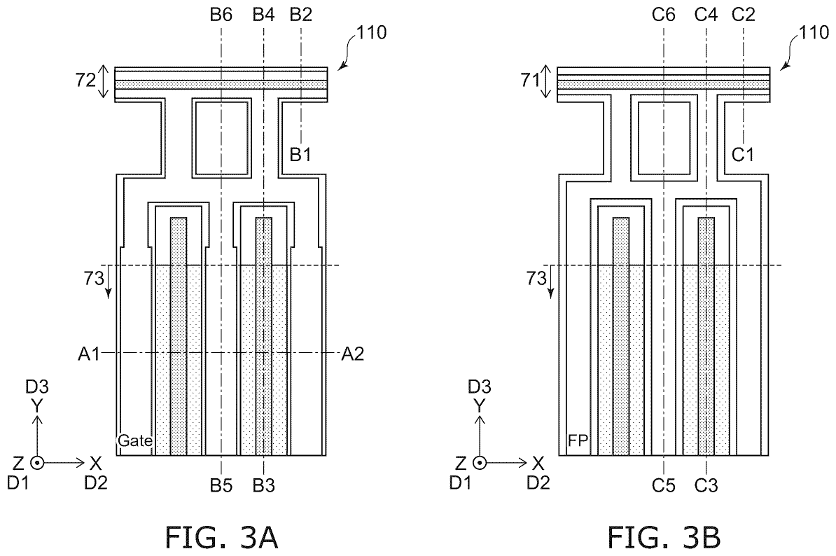

FIG. 1A is a cross-sectional view taken along the line A1-A2 in a cell region 73 of FIG. 3A. FIG. 1B is a cross-sectional view taken along the line B1-B2 in a gate connection region 72 of FIG. 3A. FIG. 1C is a cross-sectional view taken along the line C1-C2 in a source connection region 71 of FIG. 3B. FIGS. 3A and 3B will be described later.

As shown in FIG. 1A, a semiconductor device 110 according to the embodiment includes a first electrode 51, a second electrode 52, a third electrode 53, a semiconductor member 10M, a first conductive member 61, and a first insulating member 41.

A direction from the first electrode 51 to the second electrode 52 is along a first direction D1. The third electrode 53 is between the first electrode 51 and the second electrode 52 in the first direction D1. The first conductive member 61 is between the first electrode 51 and the third electrode 53 in the first direction D1. The semiconductor member 10M is provided between the first electrode 51 and the second electrode 52 in the first direction D1.

The semiconductor member 10M includes a first semiconductor region 11 of a first conductivity type and a second semiconductor region 12 of the first conductivity type. The second semiconductor region 12 is provided in the cell region 73. The second semiconductor region 12 is between the first semiconductor region 11 and the second electrode 52 in the first direction D1.

The first direction D1 is defined as a Z-axis direction. A direction perpendicular to the Z-axis direction is defined as an X-axis direction. A direction perpendicular to the Z-axis direction and the X-axis direction is defined as a Y-axis direction.

A second direction D2 from at least a part of the second semiconductor region 12 to the third electrode 53 crosses the first direction D1. The second direction D2 may be, for example, the X-axis direction. A direction from at least a part of the first semiconductor region 11 to the third electrode 53 is along the second direction D2. A direction from at least a part of the first semiconductor region 11 to the first conductive member 61 is along the second direction D2. A part of the first semiconductor region 11 is, for example, a mesa portion. A direction from another part of the first semiconductor region 11 to the first conductive member 61 is along the first direction D1.

The third electrode 53 extends, for example, along a third direction D3. The third direction D3 may be, for example, the Y-axis direction. The first conductive member 61 extends, for example, along the third direction D3. The second direction D2 crosses a plane including the first direction D1 and the third direction D3.

At least a part of the first insulating member 41 is between the first conductive member 61 and the semiconductor member 10M, and between the third electrode 53 and the semiconductor member 10M. A part of the first insulating member 41 is between the first conductive member 61 and the third electrode 53 in the first direction D1. A part of the first insulating member 41 is between the second electrode 52 and the third electrode 53 in the first direction D1.

The first conductive member 61 may include, for example, polysilicon of a first conductivity type. The first conductive member 61 may include, for example, n-type polysilicon. The third electrode 53 may include, for example, polysilicon of a second conductivity type. The third electrode 53 may include, for example, p-type polysilicon.

The second electrode 52 may include a first electrode member 52a. The first electrode member 52a includes a third material belonging to a first type material group. A direction from the first electrode member 52a to a part of the first semiconductor region 11 is along the second direction D2. A direction from the first electrode member 52a to another part of the first semiconductor region 11 is along the first direction D1. The first electrode member 52a is in Schottky contact with the first semiconductor region 11. A direction from the first electrode member 52a to the second semiconductor region 12 is along the second direction D2. The first electrode member 52a may be, for example, a trench contact. The semiconductor device 110 may be, for example, a Schottky-type MOSFET.

As shown in FIG. 1B, the semiconductor device 110 according to the embodiment includes a second connection member 32. The second connection member 32 may include a first portion 32a. The first portion 32a includes a second material belonging to the first type material group. The first portion 32a contacts the third electrode 53. In the first direction D1, an end of the first portion 32a on the first electrode 51 side is closer to the first electrode 51 than an end of the third electrode 53 on the second electrode 52 side.

As shown in FIG. 1C, the semiconductor device 110 according to the embodiment includes a first connection member 31. The first connection member 31 may include a first connection portion 31a. The first connection portion 31a includes a first material belonging to a second type material group. The first connection portion 31a contacts the first conductive member 61. An energy barrier between the first connection portion 31a and the first conductive member 61 is small. It is possible to reduce a connection resistance between the first connection portion 31a and the first conductive member 61. It is possible to reduce the contact resistance of the first conductive member 61.

In the embodiment, the contact resistance of the first conductive member 61 in a Schottky-type MOSFET can be reduced. According to the embodiment, a semiconductor device with improved characteristics can be provided.

The first type material group may include at least one selected from the group consisting of Ir, Pt, Au, Ni, Pd, Co, Mo, TiO₂, V, Ir compounds, Pt compounds, Au compounds, Ni compounds, Pd compounds, Co compounds, Mo compounds, and V compounds.

The second type material group may include at least one selected from the group consisting of Ti, Al, Fe, Cu, Cr, Mn, Zn, Ga, Ag, W, Ti nitrides, Al compounds, Fe compounds, Cu compounds, Cr compounds, Mn compounds, Zn compounds, Ga compounds, Ag compounds, and W compounds.

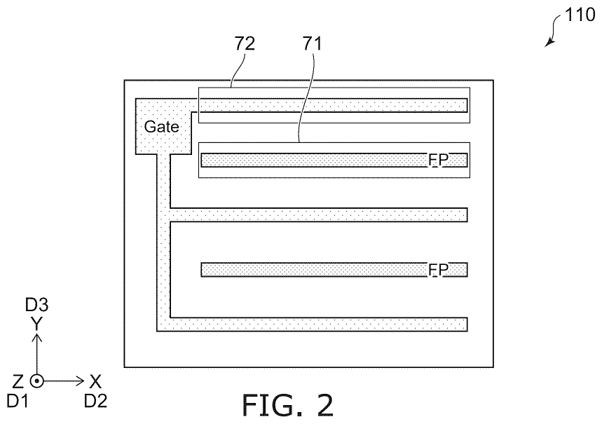

FIG. 2 is a schematic plan view illustrating the semiconductor device according to the first embodiment.

FIGS. 3A and 3B are schematic plan views illustrating the semiconductor device according to the first embodiment.

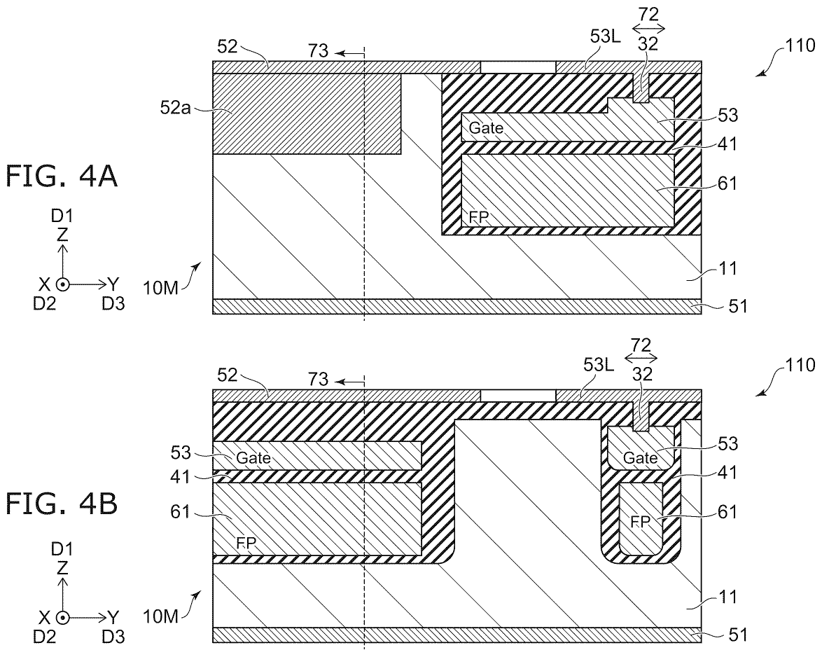

FIGS. 4A and 4B are schematic cross-sectional views illustrating the semiconductor device according to the first embodiment.

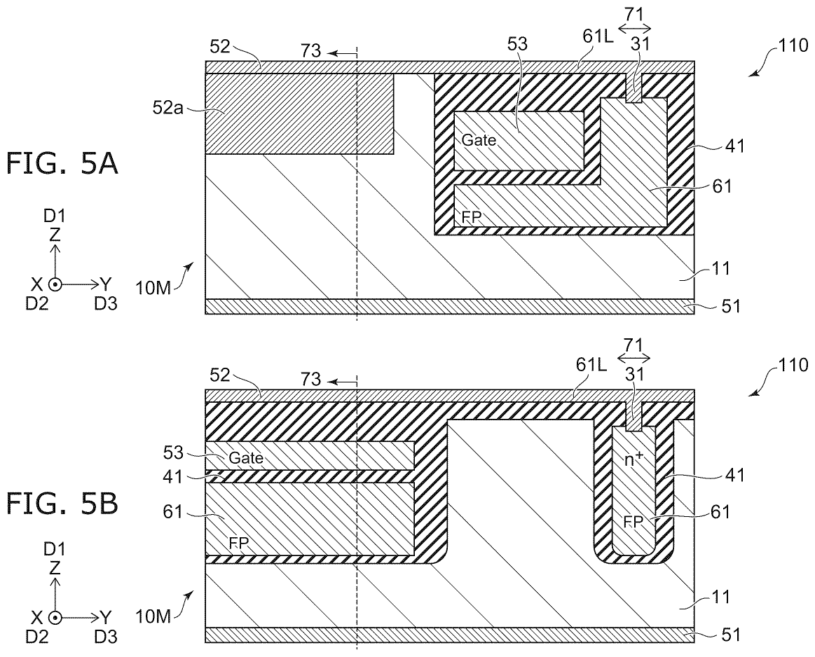

FIGS. 5A and 5B are schematic cross-sectional views illustrating the semiconductor device according to the first embodiment.

As shown in FIG. 2, the semiconductor device 110 according to the embodiment includes the source connection region 71 and the gate connection region 72. The source connection region 71 extends, for example, along the second direction D2. The gate connection region 72 extends, for example, along the second direction D2. For example, one source connection region 71 is between one gate connection region 72 and another gate connection region 72 in the third direction D3. For example, one gate connection region 72 is between one source connection region 71 and another source connection region 71 in the third direction D3.

FIG. 3A illustrates the gate connection region 72 of FIG. 2. As shown in FIG. 3A, for example, a direction from the cell region 73 (where the second semiconductor region 12 exists) to the gate connection region 72 is along the third direction D3. FIG. 3B illustrates the source connection region 71 of FIG. 2. As shown in FIG. 3B, for example, a direction from the cell region 73 to the source connection region 71 is along the third direction D3.

FIG. 4A is a cross-sectional view taken along the line B3-B4 of FIG. 3A. FIG. 4B is a cross-sectional view taken along the line B5-B6 of FIG. 3A.

As shown in FIGS. 4A and 4B, a gate wiring member 53L is provided in the gate connection region 72. The gate wiring member 53L extends along an in-plane direction formed by the second direction D2 and the third direction D3, for example, along the second direction D2. A direction from the first electrode 51 to the gate wiring member 53L is along the first direction D1. The second connection member 32 is between the third electrode 53 and the gate wiring member 53L in the first direction D1. The second connection member 32 is electrically connected to the gate wiring member 53L.

For example, the third electrode 53 extends along the second direction D2 in the gate connection region 72. For example, the second connection member 32 extends along the second direction D2 in the gate connection region 72.

FIG. 5A is a cross-sectional view taken along the line C3-C4 in FIG. 3B. FIG. 5B is a cross-sectional view taken along the line C5-C6 in FIG. 3B.

As shown in FIG. 5A and FIG. 5B, a source wiring member 61L is provided in the source connection region 71. The source wiring member 61L extends along an in-plane direction formed by the second direction D2 and the third direction D3, for example, along the second direction D2. A direction from the first electrode 51 to the source wiring member 61L is along the first direction D1. The third electrode 53 is not provided in the source connection region 71. The first connection member 31 is between the first conductive member 61 and the source wiring member 61L in the first direction D1. The first connection member 31 is electrically connected to the source wiring member 61L. For example, the source wiring member 61L may be electrically connected to the second electrode 52. For example, the first conductive member 61 may be electrically connected to the second electrode 52.

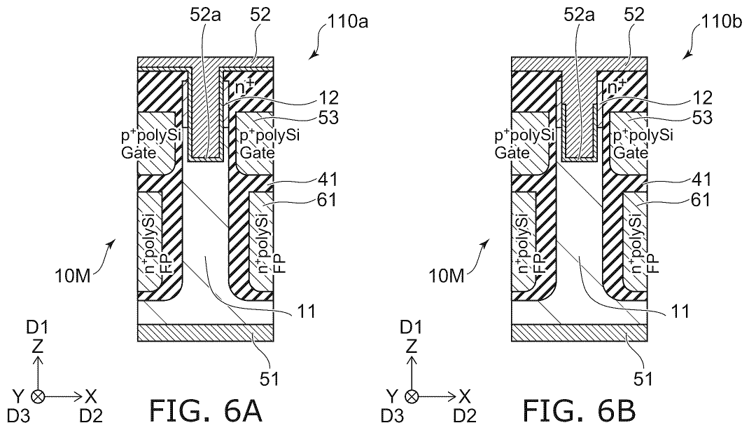

FIG. 6A and FIG. 6B are schematic cross-sectional views illustrating semiconductor devices according to the first embodiment.

FIG. 6A is a schematic cross-sectional view of the cell region 73 of a semiconductor device 110a according to the embodiment. FIG. 6B is a schematic cross-sectional view of the cell region 73 of a semiconductor device 110b according to the embodiment.

As shown in FIG. 6A, at least a part of the first electrode member 52a in the semiconductor device 110a according to the embodiment may be between the first semiconductor region 11 and the second electrode 52 in the first direction D1. At least a part of the first electrode member 52a may be between the second electrode 52 and a part of the first semiconductor region 11 in the second direction D2. At least a part of the first electrode member 52a may be between a part of the second electrode 52 and a part of the second semiconductor region 12 in the second direction D2. The configuration of the semiconductor device 110a other than this may be the same as the configuration of the semiconductor device 110. The first electrode member 52a is in contact with the first semiconductor region 11. The first electrode member 52a may be in contact with the second semiconductor region 12. The first electrode member 52a is in contact with the first semiconductor region 11 in the first direction D1 and the second direction D2. A Schottky contact is effectively obtained.

As shown in FIG. 6B, at least a part of the first electrode member 52a in a semiconductor device 110b according to the embodiment may be between the first semiconductor region 11 and the second electrode 52 in the first direction D1. At least a part of the first electrode member 52a may be between the second electrode 52 and a part of the first semiconductor region 11 in the second direction D2. At least a part of the first electrode member 52a may be between a part of the second electrode 52 and a part of the second semiconductor region 12 in the second direction D2. At least a part of the second semiconductor region 12 may be between the second electrode 52 and the first insulating member 41 in the second direction D2. The second electrode 52 may include, for example, at least one material selected from materials belonging to the second type material group. The configuration of the semiconductor device 110b other than this may be the same as the configuration of the semiconductor device 110. The second electrode 52 may be in contact with the second semiconductor region 12. The first electrode member 52a may be in contact with the second semiconductor region 12. The first electrode member 52a contacts the first semiconductor region 11 in the first direction D1 and the second direction D2. A Schottky contact is effectively obtained.

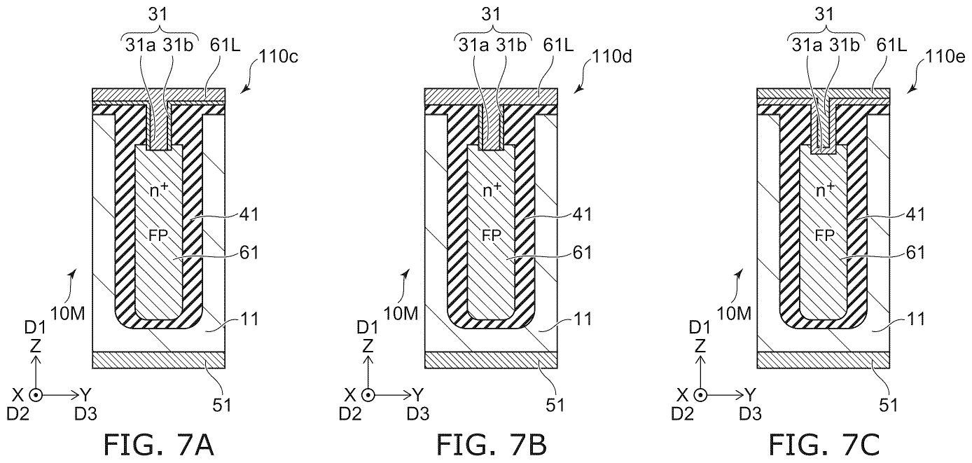

FIGS. 7A, 7B, and 7C are schematic cross-sectional views illustrating the semiconductor devices according to the first embodiment.

FIG. 7A is a schematic cross-sectional view of the source connection region 71 of a semiconductor device 110c according to the embodiment. FIG. 7B is a schematic cross-sectional view of the source connection region 71 of a semiconductor device 110d according to the embodiment. FIG. 7C is a schematic cross-sectional view of the source connection region 71 of a semiconductor device 110e according to the embodiment.

As shown in FIG. 7A, in the semiconductor device 110c according to the embodiment, for example, the first connection member 31 may include a second connection portion 31b. The second connection portion 31b may include, for example, at least one material selected from materials belonging to the first type material group.

For example, at least a part of the second connection portion 31b may be between the first connection portion 31a and the first conductive member 61, and between the first connection portion 31a and the first insulating member 41, in the third direction D3. For example, at least a part of the second connection portion 31b may be between the first insulating member 41 and the source wiring member 61L in the first direction D1. The configuration of the semiconductor device 110c other than this may be the same as the configuration of the semiconductor device 110.

For example, at least a part of the second connection portion 31b contacts the first conductive member 61. The contact area of the first connection portion 31a and the first conductive member 61 is larger than the contact area of the second connection portion 31b and the first conductive member 61. The contact resistance of the first conductive member 61 can be reduced.

As shown in FIG. 7B, at least a part of the second connection portion 31b in the semiconductor device 110d according to the embodiment may be located between the first connection portion 31a and the first conductive member 61, and between the first connection portion 31a and the first insulating member 41, in the third direction D3. The configuration of the semiconductor device 110d other than this may be the same as the configuration of the semiconductor device 110.

At least a part of the second connection portion 31b contacts the first conductive member 61. The contact area of the first connection portion 31a and the first conductive member 61 is larger than the contact area of the second connection portion 31b and the first conductive member 61. The contact resistance of the first conductive member 61 can be reduced.

As shown in FIG. 7C, the first connection portion 31a in the semiconductor device 110e according to the embodiment may be between the first conductive member 61 and the second connection portion 31b, and between the first insulating member 41 and the source wiring member 61L in the first direction D1. For example, the first connection portion 31a may be between the second connection portion 31b and the first insulating member 41 in the third direction D3. The configuration of the semiconductor device 110e other than this may be the same as the configuration of the semiconductor device 110. The second connection portion 31b does not contact the first conductive member 61. The first connection portion 31a contacts the first conductive member 61. The contact resistance of the first conductive member 61 can be reduced.

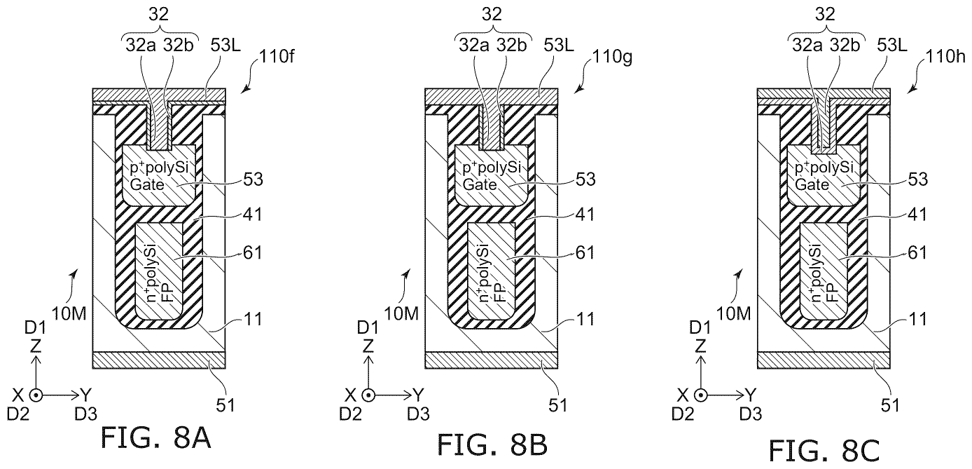

FIGS. 8A, 8B, and 8C are schematic cross-sectional views illustrating the semiconductor devices according to the first embodiment.

FIG. 8A is a schematic cross-sectional view of the gate connection region 72 of a semiconductor device 110f according to the embodiment. FIG. 8B is a schematic cross-sectional view of the gate connection region 72 of a semiconductor device 110g according to the embodiment. FIG. 8C is a schematic cross-sectional view of the gate connection region 72 of a semiconductor device 110h according to the embodiment.

As shown in FIG. 8A, in the semiconductor device 110f according to the embodiment, for example, the second connection member 32 may include the second portion 32b. The second portion 32b may include, for example, at least one material selected from materials belonging to the second type material group.

For example, at least a part of the second portion 32b may be between the first portion 32a and the third electrode 53, and between the first portion 32a and the first insulating member 41 in the third direction D3. For example, at least a part of the second portion 32b may be between the first insulating member 41 and the gate wiring member 53L in the first direction D1. The configuration of the semiconductor device 110f other than this may be the same as the configuration of the semiconductor device 110.

For example, at least a part of the second portion 32b contacts the third electrode 53. The contact area of the first portion 32a and the third electrode 53 is larger than the contact area of the second portion 32b and the third electrode 53. The energy barrier between the third electrode 53 and the first portion 32a is small.

As shown in FIG. 8B, at least a part of the second portion 32b in the semiconductor device 110g according to the embodiment may be between the first portion 32a and the third electrode 53, and between the first portion 32a and the first insulating member 41 in the third direction D3. The configuration of the semiconductor device 110g other than this may be the same as the configuration of the semiconductor device 110.

At least a part of the second portion 32b contacts the third electrode 53. The contact area of the first portion 32a and the third electrode 53 is larger than the contact area of the second portion 32b and the third electrode 53. The energy barrier between the third electrode 53 and the first portion 32a is small.

As shown in FIG. 8C, the first portion 32a in the semiconductor device 110h according to the embodiment may be between the third electrode 53 and the second portion 32b, and between the first insulating member 41 and the gate wiring member 53L in the first direction D1. For example, the first portion 32a may be between the second portion 32b and the first insulating member 41 in the third direction D3. The configuration of the semiconductor device 110h other than this may be the same as the configuration of the semiconductor device 110. The second portion 32b does not contact the third electrode 53. The first portion 32a is in contact with the third electrode 53. The energy barrier between the third electrode 53 and the first portion 32a is small.

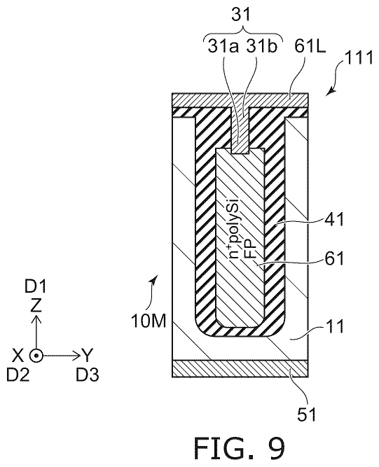

FIG. 9 is a schematic cross-sectional view illustrating a semiconductor device according to the first embodiment.

In a semiconductor device 111 according to the embodiment shown in FIG. 9, the first connection portion 31a includes a first material belonging to the first type material group. Other than this, the configuration of the semiconductor device 111 may be the same as the configuration of the semiconductor device 110.

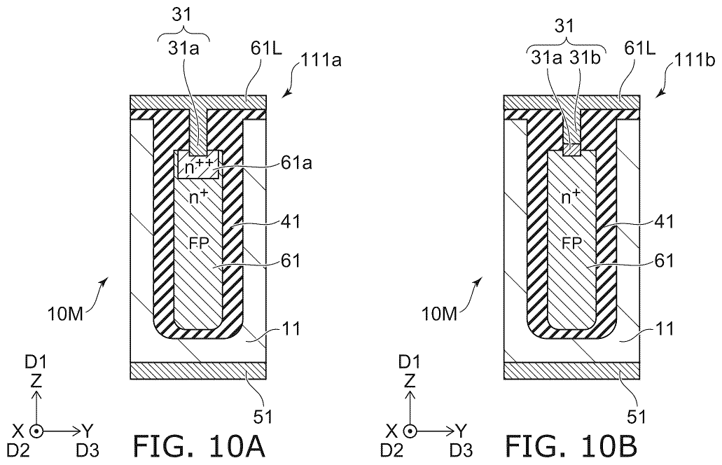

FIGS. 10A and 10B are schematic cross-sectional views illustrating semiconductor devices according to the first embodiment.

FIG. 10A is a schematic cross-sectional view of the source connection region 71 of a semiconductor device 111a according to the embodiment. FIG. 10B is a schematic cross-sectional view of the source connection region 71 of a semiconductor device 111b according to the embodiment.

As shown in FIG. 10A, in the semiconductor device 111a according to the embodiment, the first conductive member 61 may include a first connection part 61a. The first conductive member 61 is electrically connected to the first connection portion 31a at the first connection part 61a. The configuration of the semiconductor device 111a other than this may be the same as the configuration of the semiconductor device 111. For example, a first conductivity type impurity concentration in the first connection part 61a may be higher than a first conductivity type impurity concentration in the first conductive member 61 in the cell region 73. The energy barrier between the first connection part 61a and the first connection portion 31a is low.

As shown in FIG. 10B, in the semiconductor device 111b according to the embodiment, for example, the first connection member 31 may include the second connection portion 31b. The second connection portion 31b may include at least one material selected from materials belonging to the first type material group. For example, the first connection portion 31a may be located between the first conductive member 61 and the second connection portion 31b. The first connection portion 31a is electrically connected to the first conductive member 61. The configuration of the semiconductor device 111b other than this may be the same as the configuration of the semiconductor device 111. For example, the first connection portion 31a may include at least one of S, P, or As. The energy barrier between the first conductive member 61 and the first connection portion 31a is low.

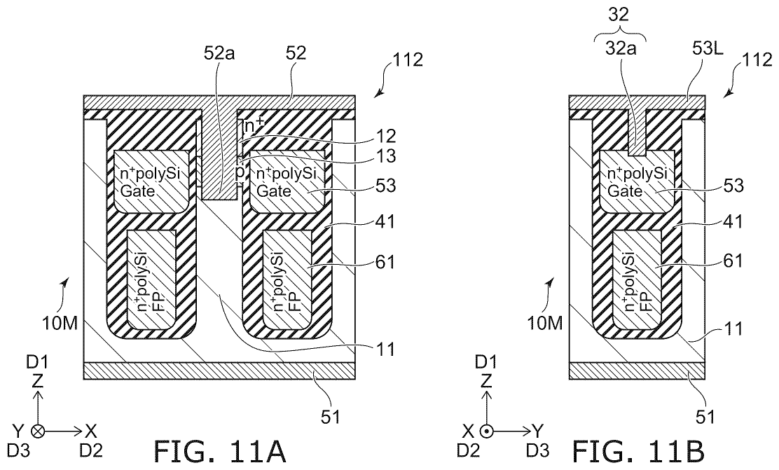

FIGS. 11A and 11B are schematic cross-sectional views illustrating a semiconductor device according to the first embodiment.

FIG. 11A is a schematic cross-sectional view of the cell region 73 of a semiconductor device 112 according to the embodiment. FIG. 11B is a schematic cross-sectional view of the gate connection region 72 of the semiconductor device 112 according to the embodiment.

In the semiconductor device 112 according to the embodiment shown in FIGS. 11A and 11B, the third electrode 53 includes, for example, polysilicon of the first conductivity type. The third electrode 53 may include, for example, n-type polysilicon. The first portion 32a includes the second material belonging to the second type material group. The semiconductor member 10M may include a third semiconductor region 13 of the second conductivity type. The third semiconductor region 13 is between the first semiconductor region 11 and the second semiconductor region 12 in the first direction D1. A direction from at least a part of the third semiconductor region 13 to the third electrode 53 is along the second direction D2. Other than this, the configuration of the semiconductor device 112 may be the same as the configuration of the semiconductor device 110.

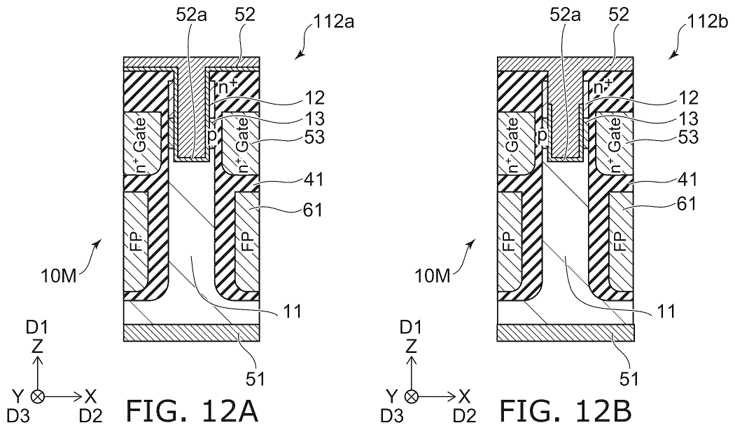

FIG. 12A and FIG. 12B are schematic cross-sectional views illustrating semiconductor devices according to the first embodiment.

FIG. 12A is a schematic cross-sectional view of the cell region 73 of a semiconductor device 112a according to the embodiment. FIG. 12B is a schematic cross-sectional view of the cell region 73 of a semiconductor device 112b according to the embodiment.

As shown in FIG. 12A, the first electrode member 52a may be between the first semiconductor region 11 and the second electrode 52. At least a part of the first electrode member 52a may be between the second electrode 52 and a part of the first semiconductor region 11 in the second direction D2. At least a part of the first electrode member 52a may be between a part of the second electrode 52 and a part of the third semiconductor region 13 in the second direction D2. At least a part of the first electrode member 52a may be between a part of the second electrode 52 and a part of the second semiconductor region 12 in the second direction D2. Other than this, the configuration of the semiconductor device 112a may be the same as the configuration of the semiconductor device 112. The first electrode member 52a contacts the first semiconductor region 11. A Schottky contact is effectively obtained.

As shown in FIG. 12B, at least a part of the first electrode member 52a may be between the first semiconductor region 11 and the second electrode 52 in the first direction D1. At least a part of the first electrode member 52a may be between the second electrode 52 and a part of the first semiconductor region 11 in the second direction D2. At least a part of the first electrode member 52a may be between the second electrode 52 and a part of the third semiconductor region 13 in the second direction D2. At least a part of the first electrode member 52a may be between a part of the second electrode 52 and a part of the second semiconductor region 12 in the second direction D2. At least a part of the second semiconductor region 12 may be between the second electrode 52 and the first insulating member 41 in the second direction D2. The second electrode 52 may include, for example, at least one material selected from materials belonging to the second type material group. The configuration of the semiconductor device 112b other than this may be the same as the configuration of the semiconductor device 112. The second electrode 52 may be in contact with the second semiconductor region 12. The first electrode member 52a may be in contact with the second semiconductor region 12. The first electrode member 52a may be in contact with the third semiconductor region 13. The second electrode 52 does not contact the first semiconductor region 11. The first electrode member 52a contacts the first semiconductor region 11 in the first direction D1 and the second direction D2. A Schottky contact is effectively obtained.

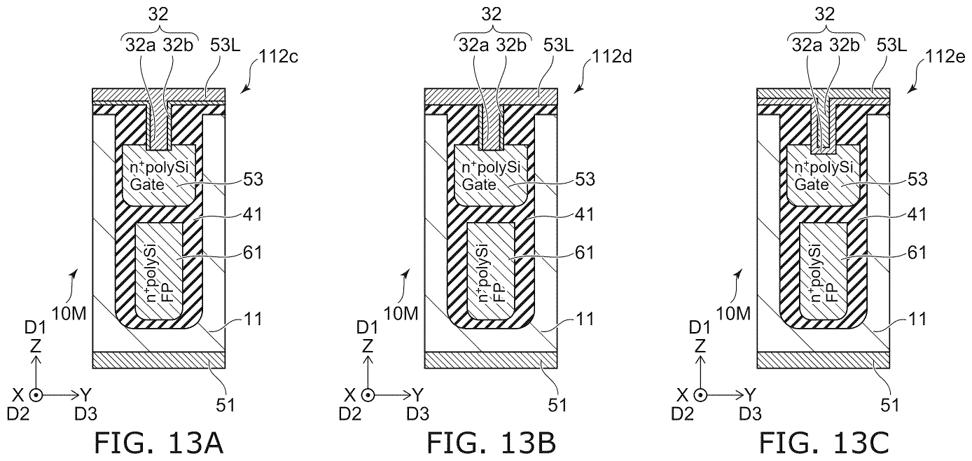

FIGS. 13A, 13B, and 13C are schematic cross-sectional views illustrating the semiconductor devices according to the first embodiment.

FIG. 13A is a schematic cross-sectional view of the gate connection region 72 of a semiconductor device 112c according to the embodiment. FIG. 13B is a schematic cross-sectional view of the gate connection region 72 of a semiconductor device 112d according to the embodiment. FIG. 13(c) is a schematic cross-sectional view of the gate connection region 72 of a semiconductor device 112e according to the embodiment.

As shown in FIG. 13A, for example, the second connection member 32 may include the second portion 32b. The second portion 32b may include, for example, at least one material selected from materials belonging to the first type material group.

For example, at least a part of the second portion 32b may be between the first portion 32a and the third electrode 53, and between the first portion 32a and the first insulating member 41 in the third direction D3. For example, at least a part of the second portion 32b may be between the first insulating member 41 and the gate wiring member 53L in the first direction D1. The configuration of the semiconductor device 112c other than this may be the same as the configuration of the semiconductor device 112.

For example, at least a part of the second portion 32b contacts the third electrode 53. The contact area of the first portion 32a and the third electrode 53 is larger than the contact area of the second portion 32b and the third electrode 53. The energy barrier between the third electrode 53 and the first portion 32a is small.

As shown in FIG. 13B, for example, at least a part of the second portion 32b may be between the first portion 32a and the third electrode 53, and between the first portion 32a and the first insulating member 41 in the third direction D3. The configuration of the semiconductor device 112d other than this may be the same as the configuration of the semiconductor device 112.

At least a part of the second portion 32b contacts the third electrode 53. The contact area of the first portion 32a and the third electrode 53 is larger than the contact area of the second portion 32b and the third electrode 53. The energy barrier between the third electrode 53 and the first portion 32a is small.

As shown in FIG. 13C, for example, the first portion 32a may be between the third electrode 53 and the second portion 32b, and between the first insulating member 41 and the gate wiring member 53L in the first direction D1. For example, the first portion 32a may be between the second portion 32b and the first insulating member 41 in the third direction D3. The configuration of the semiconductor device 112e other than this may be the same as the configuration of the semiconductor device 112. The second portion 32b does not contact the third electrode 53. The first portion 32a contacts the third electrode 53. The energy barrier between the third electrode 53 and the first portion 32a is small.

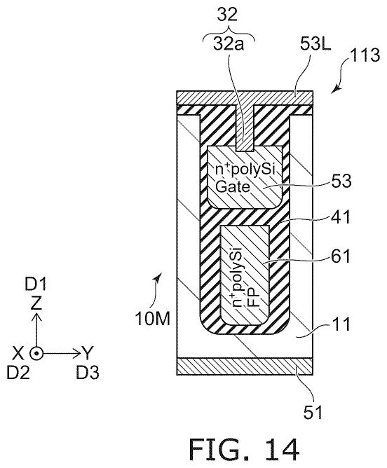

FIG. 14 is a schematic cross-sectional view illustrating a semiconductor device according to the first embodiment.

FIG. 14 is a schematic cross-sectional view of a gate connection region 72 of a semiconductor device 113 according to the embodiment.

In the semiconductor device 113 according to the embodiment shown in FIG. 14, the configuration of the source connection region 71 may be the same as the configuration of the semiconductor device 111. In the semiconductor device 113, the first portion 32a includes the first material belonging to the first type material group. The third electrode 53 includes, for example, polysilicon of the first conductivity type. The third electrode 53 may include, for example, n-type polysilicon. The configuration of the semiconductor device 113 other than this may be the same as the configuration of the semiconductor device 112.

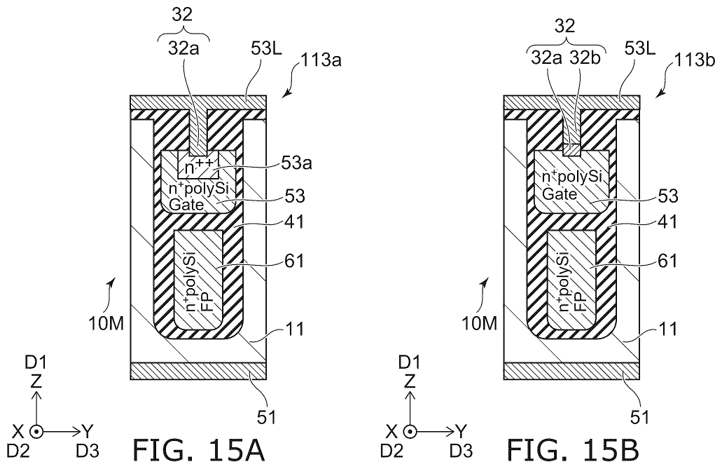

FIGS. 15A and 15B are schematic cross-sectional views illustrating semiconductor devices according to the first embodiment.

FIG. 15A is a schematic cross-sectional view of the gate connection region 72 of a semiconductor device 113a according to the embodiment.

FIG. 15B is a schematic cross-sectional view of the gate connection region 72 of a semiconductor device 113b according to the embodiment.

As shown in FIG. 15A, in the semiconductor device 113a according to the embodiment, the third electrode 53 may include a first part 53a. The first part 53a is electrically connected to the first portion 32a. The configuration of the semiconductor device 113a other than this may be the same as the configuration of the semiconductor device 113. For example, the first conductivity type impurity concentration in the first part 53a may be higher than the first conductivity type impurity concentration in the third electrode 53 in the cell region 73. The energy barrier between the first part 53a and the first portion 32a is low.

As shown in FIG. 15B, in the semiconductor device 113b according to the embodiment, for example, the second connection member 32 may include the second portion 32b. The second portion 32b may include at least one material selected from materials belonging to the first type material group. For example, the first portion 32a may be between the third electrode 53 and the second portion 32b. The first portion 32a is electrically connected to the third electrode 53. The configuration of the semiconductor device 113b other than this may be the same as the configuration of the semiconductor device 113. For example, the first portion 32a may include at least one of P, As, or S. The energy barrier between the third electrode 53 and the first portion 32a is low.

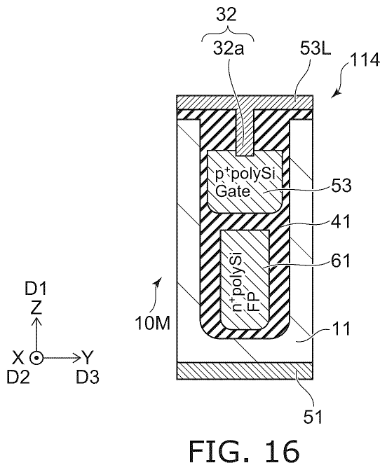

FIG. 16 is a schematic cross-sectional view illustrating a semiconductor device according to the first embodiment.

In a semiconductor device 114 according to the embodiment shown in FIG. 16, the first portion 32a includes the second material belonging to the second type material group. Other than this, the configuration of the semiconductor device 114 may be the same as the configuration of the semiconductor device 110.

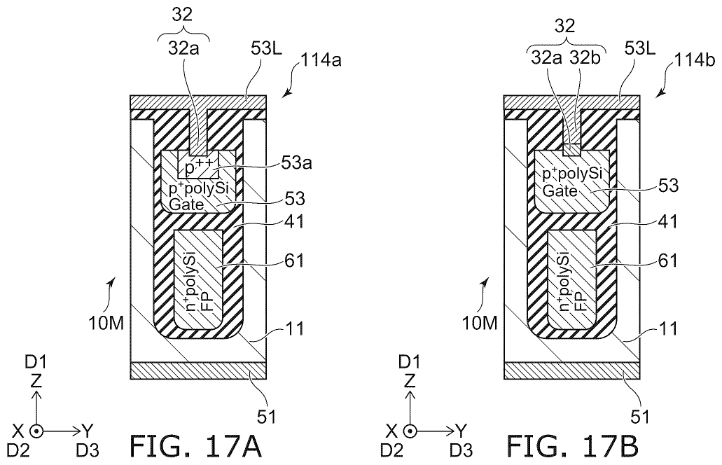

FIGS. 17A and 17B are schematic cross-sectional views illustrating semiconductor devices according to the first embodiment.

FIG. 17A is a schematic cross-sectional view of the gate connection region 72 of a semiconductor device 114a according to the embodiment. FIG. 17B is a schematic cross-sectional view of the gate connection region 72 of a semiconductor device 114b according to the embodiment.

As shown in FIG. 17A, in the semiconductor device 114a according to the embodiment, the third electrode 53 may include the first part 53a. The first part 53a is electrically connected to the first portion 32a. Ther than this, the configuration of the semiconductor device 114a may be the same as the configuration of the semiconductor device 114. For example, the second conductivity type impurity concentration in the first part 53a may be higher than the second conductivity type impurity concentration in the third electrode 53 in the cell region 73. The energy barrier between the first part 53a and the first portion 32a is low.

As shown in FIG. 17B, in the semiconductor device 114b according to the embodiment, for example, the second connection member 32 may include the second portion 32b. The second portion 32b may include at least one material selected from materials belonging to the first type material group. For example, the first portion 32a may be between the third electrode 53 and the second portion 32b. The first portion 32a is electrically connected to the third electrode 53. Other than this, the configuration of the semiconductor device 114b may be the same as the configuration of the semiconductor device 114. For example, the first portion 32a may include at least one of B or In. The energy barrier between the third electrode 53 and the first portion 32a is low.

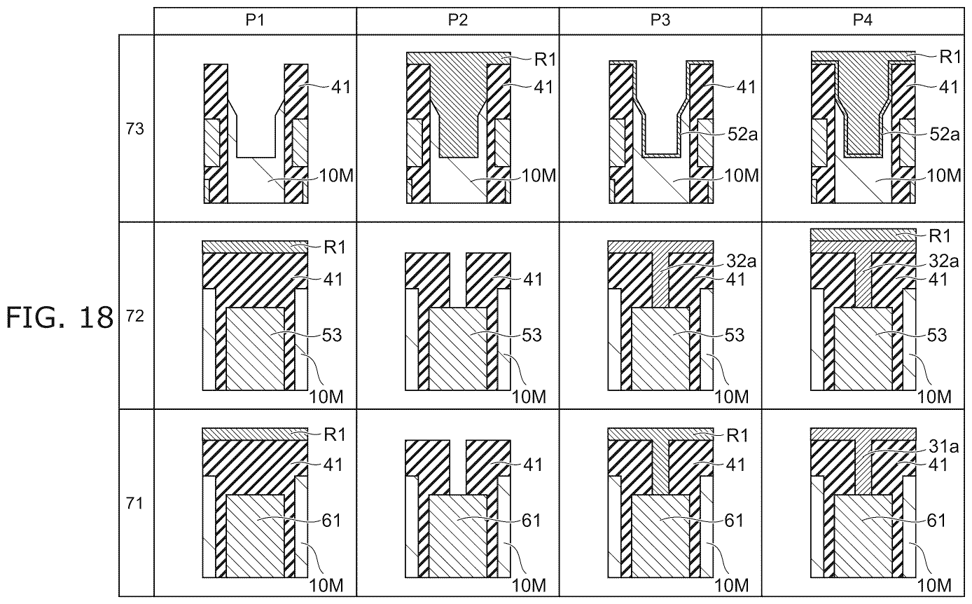

FIG. 18 is a schematic diagram illustrating a method for manufacturing a semiconductor device according to the first embodiment.

As shown in FIG. 18, a method for manufacturing the semiconductor device 110 according to the embodiment includes at least a first process P1, a second process P2, a third process P3, and a fourth process P4.

In the first process P1, a trench is formed in the semiconductor member 10M by etching in the cell region 73. The gate connection region 72 and the source connection region 71 are protected from etching by a resist member R1.

In the second process P2, openings are formed in the first insulating member 41 by etching in the gate connection region 72 and the source connection region 71. The cell region 73 is protected from etching by the resist member R1.

In the third process P3, the first electrode member 52a is formed in the cell region 73 from the third material belonging to the first type material group. In the gate connection region 72, the first portion 32a is formed from a second material belonging to the first type material group. The source connection region 71 is protected by the resist member R1.

In the fourth process P4, the first connection portion 31a is formed in the source connection region 71 from the first material belonging to the second type material group. The cell region 73 and the gate connection region 72 are protected by the resist member R1.

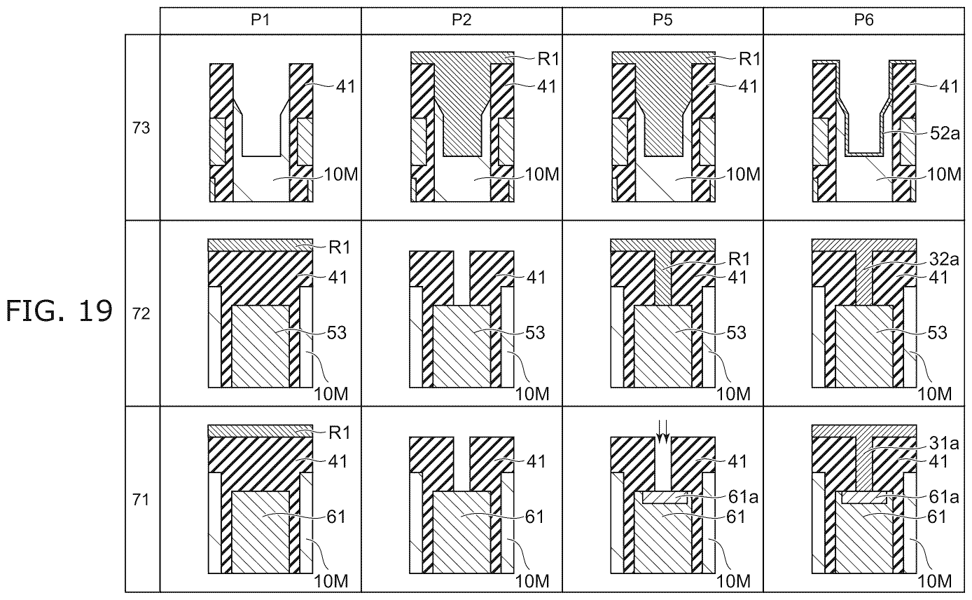

FIG. 19 is a schematic diagram illustrating a method for manufacturing a semiconductor device according to the first embodiment.

As shown in FIG. 19, a method for manufacturing the semiconductor device 111 according to the embodiment includes at least the first process P1, the second process P2, the fifth process P5, and the sixth process P6. The first process P1 and the second process P2 are the same as the method for manufacturing the semiconductor device 110.

In the fifth process P5, ions are implanted in the source connection region 71 to form the first connection part 61a. The cell region 73 and the gate connection region 72 are protected by the resist member R1.

In the sixth process P6, the first electrode member 52a is formed in the cell region 73 from the third material belonging to the first type material group. In the gate connection region 72, the first portion 32a is formed from the second material belonging to the first type material group. In the source connection region 71, the first connection portion 31a is formed from the first material belonging to the first type material group.

In the embodiment, the first conductivity type is one of n-type and p-type. The first conductivity type may be, for example, n-type. The impurity concentration of the first conductivity type in the first semiconductor region 11 may be, for example, not less than 1×10¹⁵ cm⁻³ and not more than 1×10¹⁷ cm⁻³. The impurity concentration of the first conductivity type in the second semiconductor region 12 may be, for example, not less than 1×10¹⁸ cm⁻³ and not more than 1×10²¹ cm⁻³.

In the embodiment, at least one of the first electrode 51 or the second electrode 52 may include a metal. The metal may include at least one selected from the group consisting of Al, Ti, Ni, Au, Ag, and Cu. At least one of the third electrode 53 or the first conductive member 61 may include polysilicon.

In the embodiments, information on the shape of the semiconductor region is obtained, for example, from an electron microscope image. Information on the composition and element concentration is obtained, for example, from EDX (Energy Dispersive X-ray Spectroscopy) or SIMS (Secondary Ion Mass Spectrometry). Information on the composition may be obtained, for example, from reciprocal space mapping.

The embodiments may include the following Technical proposals:

### (Technical Proposal 1)

A semiconductor device, comprising:
a first electrode;
a second electrode including a first electrode member, a direction from the first electrode to the second electrode being along a first direction;
a third electrode provided between the first electrode and the second electrode and including polysilicon of a second conductivity type,
a first conductive member provided between the first electrode and the third electrode in the first direction and including polysilicon of a first conductivity type,
a semiconductor member provided between the first electrode and the second electrode, the semiconductor member including a first semiconductor region of the first conductivity type and a second semiconductor region of the first conductivity type, the second semiconductor region being between the first semiconductor region and the second electrode, a direction from a part of the third electrode to the second semiconductor region crossing the first direction;
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a second type material group,
the first connection portion being electrically connected to the first conductive member,
the first portion including a second material belonging to a first type material group different from the second type material group,
the first portion being electrically connected to the third electrode,
the first electrode member being between the semiconductor member and the second electrode,
the first electrode member including a third material belonging to the first type material group, and
the first electrode member being in Schottky contact with the semiconductor member.

### (Technical Proposal 2)

The semiconductor device according to Technical proposal 1, wherein
the first connection member further includes a second connection portion,
the second connection portion does not include a material belonging to the second type material group, and
an area of a region where the first conductive member is in contact with the first connection portion is larger than an area of a region where the first conductive member is in contact with the second connection portion.

### (Technical Proposal 3)

The semiconductor device according to Technical proposal 1 or 2, wherein
the second connection member further includes a second portion,
the second portion does not include a material belonging to the first type material group, and
an area of a region where the third electrode is in contact with the first portion is larger than an area of a region where the third electrode is in contact with the second portion.

### (Technical Proposal 4)

A semiconductor device, comprising:
a first electrode;
a second electrode including a first electrode member, a direction form from the first electrode to the second electrode being along a first direction;
a third electrode provided between the first electrode and the second electrode and including polysilicon of a second conductivity type;
a first conductive member provided between the first electrode and the third electrode in the first direction and including polysilicon of a first conductivity type,
a semiconductor member provided between the first electrode and the second electrode, the semiconductor member including a first semiconductor region of the first conductivity type and a second semiconductor region of the first conductivity type, the second semiconductor region being between the first semiconductor region and the second electrode, a direction from a part of the third electrode to the second semiconductor region crossing the first direction,
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a first type material group,
the first connection portion being electrically connected to the first conductive member,
the first portion including a second material belonging to the first type material group,
the first portion being electrically connected to the third electrode,
the first electrode member being between the semiconductor member and the second electrode,
the first electrode member including a third material belonging to the first type material group, and
the first electrode member being in Schottky contact with the semiconductor member.

### (Technical Proposal 5)

The semiconductor device according to Technical proposal 4, further comprising:
a cell region,
the first conductive member including a first connection part,
the first connection part being electrically connected to the first connection member, and
a first conductivity type impurity concentration in the first connection part is higher than a first conductivity type impurity concentration in the first conductive member in the cell region.

### (Technical Proposal 6)

The semiconductor device according to Technical proposal 4 or 5, wherein
the first connection portion includes at least one of S, P, or As.

### (Technical Proposal 7)

A semiconductor device, comprising:
a first electrode;
a second electrode including a first electrode member, a first direction from the first electrode to the second electrode being along a first direction;
a third electrode provided between the first electrode and the second electrode, and including polysilicon of a first conductivity type;
a first conductive member provided between the first electrode and the third electrode in the first direction and including polysilicon of the first conductivity type;
a semiconductor member provided between the first electrode and the second electrode, the semiconductor member including a first semiconductor region of the first conductivity type and a second semiconductor region of the first conductivity type, the second semiconductor region being between the first semiconductor region and the second electrode, a direction from a part of the third electrode to the second semiconductor region crossing the first direction;
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a second type material group,
the first connection portion being electrically connected to the first conductive member,
the first portion including a second material belonging to the second type material group,
the first portion being electrically connected to the third electrode,
the first electrode member being between the semiconductor member and the second electrode,
the first electrode member including a third material belonging to a first type material group different from the second type material group, and
the first electrode member being in Schottky contact with the semiconductor member.

### (Technical Proposal 8)

The semiconductor device according to Technical proposal 7, wherein
the semiconductor member further includes a third semiconductor region of a second conductivity type,
the third semiconductor region is between the first semiconductor region and the second semiconductor region in the first direction,
a direction from a part of the third electrode to the third semiconductor region crosses the first direction, and
the first electrode member is in contact with the first semiconductor region.

### (Technical Proposal 9)

The semiconductor device according to Technical proposal 7 or 8, wherein
the first connection member further includes a second connection portion,
the second connection portion does not include a material belonging to the second type material group, and
an area of a region where the first conductive member is in contact with the first connection portion is larger than an area of a region where the first conductive member is in contact with the second connection portion.

### (Technical Proposal 10)

The semiconductor device according to Technical proposal 7 or 8, wherein
the second connection member further includes a second portion,
the second portion does not include a material belonging to the second type material group, and
an area of a region where the third electrode is in contact with the first portion is larger than an area of a region where the third electrode is in contact with the second portion.

### (Technical Proposal 11)

A semiconductor device, comprising:
a first electrode;
a second electrode including a first electrode member, a first direction from the first electrode to the second electrode being along a first direction;
a third electrode provided between the first electrode and the second electrode, and including polysilicon of a first conductivity type;
a first conductive member provided between the first electrode and the third electrode in the first direction and including polysilicon of the first conductivity type;
a semiconductor member provided between the first electrode and the second electrode, the semiconductor member including a first semiconductor region of a first conductivity type and a second semiconductor region of the first conductivity type, the second semiconductor region being between the first semiconductor region and the second electrode, a direction from a part of the third electrode to the second semiconductor region crossing the first direction,
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a first type material group,
the first connection portion being electrically connected to the first conductive member,
the first portion including a second material belonging to the first type material group,
the first portion being electrically connected to the third electrode,
the first electrode member being between the semiconductor member and the second electrode,
the first electrode member including a third material belonging to the first type material group, and
the first electrode member being in Schottky contact with the semiconductor member.

### (Technical Proposal 12)

The semiconductor device according to Technical proposal 11, wherein
the semiconductor member further includes a third semiconductor region of a second conductivity type,
the third semiconductor region is between the first semiconductor region and the second semiconductor region in the first direction,
a direction from a part of the third electrode to the third semiconductor region crosses the first direction, and
the first electrode member contacts the first semiconductor region.

### (Technical Proposal 13)

The semiconductor device according to Technical proposal 11 or 12, further comprising:
a cell region,
the first conductive member including a first connection part,
the first connection part being electrically connected to the first connection member,
a first conductivity type impurity concentration in the first connection part being higher than a first conductivity type impurity concentration in the first conductive member in the cell region,
the third electrode including a first part,
the first part being electrically connected to the second connection member, and
a first conductivity type impurity concentration in the first part being higher than a first conductivity type impurity concentration in the third electrode in the cell region.

### (Technical Proposal 14)

The semiconductor device according to Technical proposal 11 or 12, wherein
the first portion includes at least one of S, P, or As.

### (Technical Proposal 15)

A semiconductor device, comprising:
a first electrode,
a second electrode including a first electrode member, a first direction from the first electrode to the second electrode being along a first direction;
a third electrode provided between the first electrode and the second electrode and including polysilicon of a second conductivity type;
a first conductive member provided between the first electrode and the third electrode in the first direction and including polysilicon of the first conductivity type,
a semiconductor member provided between the first electrode and the second electrode, the semiconductor member including a first semiconductor region of a first conductivity type and a second semiconductor region of the first conductivity type, the second semiconductor region being between the first semiconductor region and the second electrode, a direction from a part of the third electrode to the second semiconductor region crossing the first direction;
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a second type material group,
the first connection portion being electrically connected to the first conductive member,
the first portion including a second material belonging to the second type material group,
the first portion being electrically connected to the third electrode,
the first electrode member being between the semiconductor member and the second electrode,
the first electrode member including a third material belonging to a first type material group different from the second type material group, and
the first electrode member being in Schottky contact with the semiconductor member.

### (Technical Proposal 16)

The semiconductor device according to Technical proposal 15, wherein
the first connection member further includes a second connection portion,
the second connection portion does not include a material belonging to the second type material group, and
an area of the region where the first conductive member is in contact with the first connection portion is larger than an area of the region where the first conductive member is in contact with the second connection portion.

### (Technical Proposal 17)

The semiconductor device according to Technical proposal 15 or 16, wherein
the second connection member further includes a second portion,
the second portion does not include a material belonging to the second type material group, and
an area of a region where the third electrode is in contact with the first portion is larger than an area of a region where the third electrode is in contact with the second portion.

### (Technical Proposal 18)

The semiconductor device according to Technical proposal 15, further comprising:
a cell region,
the third electrode including a first part;
the first part being electrically connected to the first connection member, and
a second conductivity type impurity concentration in the first part being higher than a second conductivity type impurity concentration in the third electrode in the cell region.

### (Technical Proposal 19)

The semiconductor device according to Technical proposal 15 or 18, wherein
the first portion includes at least one of B or In.

### (Technical Proposal 20)

The semiconductor device according to any one of Technical proposals 1, 7, and 15, wherein
the first type material group includes at least one selected from the group consisting of Ir, Pt, Au, Ni, Pd, Co, Mo, TiO₂, V, Ir compounds, Pt compounds, Au compounds, Ni compounds, Pd compounds, Co compounds, Mo compounds, and V compounds,
the second type material group includes at least one selected from the group consisting of Ti, Al, Fe, Cu, Cr, Mn, Zn, Ga, Ag, W, Ti nitrides, Al compounds, Fe compounds, Cu compounds, Cr compounds, Mn compounds, Zn compounds, Ga compounds, Ag compounds, and W compounds.

### (Technical Proposal 21)

The semiconductor device according to Technical proposal 4 or 11, wherein
the first type material group includes at least one selected from the group consisting of Ir, Pt, Au, Ni, Pd, Co, Mo, TiO₂, V, Ir compounds, Pt compounds, Au compounds, Ni compounds, Pd compounds, Co compounds, Mo compounds, and V compounds.

### (Technical Proposal 22)

The semiconductor device according to any one of technical proposals 1, 4, 7, 11, and 15, further comprising:
a cell region;
a source connection region; and
a gate connection region,
in the source connection region, the first connection portion being electrically connected to the first conductive member,
in the gate connection region, the first portion being electrically connected to the third electrode, and
in the cell region, the first electrode member being in Schottky contact with the semiconductor member.

According to an embodiment, a semiconductor device is provided that can improve characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, conductive portions, semiconductor members, semiconductor regions, conductive members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode including a first electrode member, a direction from the first electrode to the second electrode being along a first direction;
a third electrode provided between the first electrode and the second electrode and including polysilicon of a second conductivity type,
a first conductive member provided between the first electrode and the third electrode in the first direction and including polysilicon of a first conductivity type,
a semiconductor member provided between the first electrode and the second electrode, the semiconductor member including a first semiconductor region of the first conductivity type and a second semiconductor region of the first conductivity type, the second semiconductor region being between the first semiconductor region and the second electrode, a direction from a part of the third electrode to the second semiconductor region crossing the first direction;
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a second type material group,
the first connection portion being electrically connected to the first conductive member,
the first portion including a second material belonging to a first type material group different from the second type material group,
the first portion being electrically connected to the third electrode,
the first electrode member being between the semiconductor member and the second electrode,
the first electrode member including a third material belonging to the first type material group, and
the first electrode member being in Schottky contact with the semiconductor member.

2. The semiconductor device according to claim 1, wherein
the first connection member further includes a second connection portion,
the second connection portion does not include a material belonging to the second type material group, and
an area of a region where the first conductive member is in contact with the first connection portion is larger than an area of a region where the first conductive member is in contact with the second connection portion.

3. The semiconductor device according to claim 1, wherein
the second connection member further includes a second portion,
the second portion does not include a material belonging to the first type material group, and
an area of a region where the third electrode is in contact with the first portion is larger than an area of a region where the third electrode is in contact with the second portion.

4. A semiconductor device, comprising:
a first electrode;
a second electrode including a first electrode member, a direction form from the first electrode to the second electrode being along a first direction;
a third electrode provided between the first electrode and the second electrode and including polysilicon of a second conductivity type;
a first conductive member provided between the first electrode and the third electrode in the first direction and including polysilicon of a first conductivity type,
a semiconductor member provided between the first electrode and the second electrode, the semiconductor member including a first semiconductor region of the first conductivity type and a second semiconductor region of the first conductivity type, the second semiconductor region being between the first semiconductor region and the second electrode, a direction from a part of the third electrode to the second semiconductor region crossing the first direction,
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a first type material group,
the first connection portion being electrically connected to the first conductive member,
the first portion including a second material belonging to the first type material group,
the first portion being electrically connected to the third electrode,
the first electrode member being between the semiconductor member and the second electrode,
the first electrode member including a third material belonging to the first type material group, and
the first electrode member being in Schottky contact with the semiconductor member.

5. The semiconductor device according to claim 4, further comprising:
a cell region,
the first conductive member including a first connection part,
the first connection part being electrically connected to the first connection member, and
a first conductivity type impurity concentration in the first connection part is higher than a first conductivity type impurity concentration in the first conductive member in the cell region.

6. The semiconductor device according to claim 4, wherein
the first connection portion includes at least one of S, P, or As.

7. A semiconductor device, comprising:
a first electrode;
a second electrode including a first electrode member, a first direction from the first electrode to the second electrode being along a first direction;
a third electrode provided between the first electrode and the second electrode, and including polysilicon of a first conductivity type;
a first conductive member provided between the first electrode and the third electrode in the first direction and including polysilicon of the first conductivity type;
a semiconductor member provided between the first electrode and the second electrode, the semiconductor member including a first semiconductor region of the first conductivity type and a second semiconductor region of the first conductivity type, the second semiconductor region being between the first semiconductor region and the second electrode, a direction from a part of the third electrode to the second semiconductor region crossing the first direction;
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a second type material group,
the first connection portion being electrically connected to the first conductive member,
the first portion including a second material belonging to the second type material group,
the first portion being electrically connected to the third electrode,
the first electrode member being between the semiconductor member and the second electrode,
the first electrode member including a third material belonging to a first type material group different from the second type material group, and
the first electrode member being in Schottky contact with the semiconductor member.

8. The semiconductor device according to claim 7, wherein
the semiconductor member further includes a third semiconductor region of a second conductivity type,
the third semiconductor region is between the first semiconductor region and the second semiconductor region in the first direction,
a direction from a part of the third electrode to the third semiconductor region crosses the first direction, and
the first electrode member is in contact with the first semiconductor region.

9. The semiconductor device according to claim 7, wherein
the first connection member further includes a second connection portion,
the second connection portion does not include a material belonging to the second type material group, and
an area of a region where the first conductive member is in contact with the first connection portion is larger than an area of a region where the first conductive member is in contact with the second connection portion.

10. The semiconductor device according to claim 7, wherein
the second connection member further includes a second portion,
the second portion does not include a material belonging to the second type material group, and
an area of a region where the third electrode is in contact with the first portion is larger than an area of a region where the third electrode is in contact with the second portion.

11. A semiconductor device, comprising:
a first electrode;
a second electrode including a first electrode member, a first direction from the first electrode to the second electrode being along a first direction;
a third electrode provided between the first electrode and the second electrode, and including polysilicon of a first conductivity type;
a first conductive member provided between the first electrode and the third electrode in the first direction and including polysilicon of the first conductivity type;
a semiconductor member provided between the first electrode and the second electrode, the semiconductor member including a first semiconductor region of a first conductivity type and a second semiconductor region of the first conductivity type, the second semiconductor region being between the first semiconductor region and the second electrode, a direction from a part of the third electrode to the second semiconductor region crossing the first direction,
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a first type material group,
the first connection portion being electrically connected to the first conductive member,
the first portion including a second material belonging to the first type material group,
the first portion being electrically connected to the third electrode,
the first electrode member being between the semiconductor member and the second electrode,
the first electrode member including a third material belonging to the first type material group, and
the first electrode member being in Schottky contact with the semiconductor member.

12. The semiconductor device according to claim 11, wherein
the semiconductor member further includes a third semiconductor region of a second conductivity type,
the third semiconductor region is between the first semiconductor region and the second semiconductor region in the first direction,
a direction from a part of the third electrode to the third semiconductor region crosses the first direction, and
the first electrode member contacts the first semiconductor region.

13. The semiconductor device according to claim 11, further comprising:
a cell region,
the first conductive member including a first connection part,
the first connection part being electrically connected to the first connection member,
a first conductivity type impurity concentration in the first connection part being higher than a first conductivity type impurity concentration in the first conductive member in the cell region,
the third electrode including a first part,
the first part being electrically connected to the second connection member, and
a first conductivity type impurity concentration in the first part being higher than a first conductivity type impurity concentration in the third electrode in the cell region.

14. The semiconductor device according to claim 11, wherein
the first portion includes at least one of S, P, or As.

15. A semiconductor device, comprising:
a first electrode,
a second electrode including a first electrode member, a first direction from the first electrode to the second electrode being along a first direction;
a third electrode provided between the first electrode and the second electrode and including polysilicon of a second conductivity type;
a first conductive member provided between the first electrode and the third electrode in the first direction and including polysilicon of the first conductivity type,
a semiconductor member provided between the first electrode and the second electrode, the semiconductor member including a first semiconductor region of a first conductivity type and a second semiconductor region of the first conductivity type, the second semiconductor region being between the first semiconductor region and the second electrode, a direction from a part of the third electrode to the second semiconductor region crossing the first direction;
a first insulating member, at least a part of the first insulating member being between the first conductive member and the semiconductor member and between the third electrode and the semiconductor member;
a first connection member including a first connection portion; and
a second connection member including a first portion,
the first connection portion including a first material belonging to a second type material group,
the first connection portion being electrically connected to the first conductive member,
the first portion including a second material belonging to the second type material group,
the first portion being electrically connected to the third electrode,
the first electrode member being between the semiconductor member and the second electrode,
the first electrode member including a third material belonging to a first type material group different from the second type material group, and
the first electrode member being in Schottky contact with the semiconductor member.

16. The semiconductor device according to claim 15, wherein
the first connection member further includes a second connection portion,
the second connection portion does not include a material belonging to the second type material group, and
an area of the region where the first conductive member is in contact with the first connection portion is larger than an area of the region where the first conductive member is in contact with the second connection portion.

17. The semiconductor device according to claim 15, wherein
the second connection member further includes a second portion,
the second portion does not include a material belonging to the second type material group, and
an area of a region where the third electrode is in contact with the first portion is larger than an area of a region where the third electrode is in contact with the second portion.

18. The semiconductor device according to claim 15, further comprising:
a cell region,
the third electrode including a first part;
the first part being electrically connected to the first connection member, and
a second conductivity type impurity concentration in the first part being higher than a second conductivity type impurity concentration in the third electrode in the cell region.

19. The semiconductor device according to claim 15, wherein
the first portion includes at least one of B or In.

20. The semiconductor device according to claim 1, wherein
the first type material group includes at least one selected from the group consisting of Ir, Pt, Au, Ni, Pd, Co, Mo, TiO₂, V, Ir compounds, Pt compounds, Au compounds, Ni compounds, Pd compounds, Co compounds, Mo compounds, and V compounds,
the second type material group includes at least one selected from the group consisting of Ti, Al, Fe, Cu, Cr, Mn, Zn, Ga, Ag, W, Ti nitrides, Al compounds, Fe compounds, Cu compounds, Cr compounds, Mn compounds, Zn compounds, Ga compounds, Ag compounds, and W compounds.
